(19) United States
(12) Patent Application Publication
(10) Pub. No.: US 2024/0423041 A1
(43) Pub. Date: Dec. 19, 2024

(54) DISPLAY DEVICE

(71) Applicant: Samsung Display Co., LTD., Yongin-si (KR)

(72) Inventors: Kang Moon JO, Yongin-si (KR); Sun Kwang KIM, Yongin-si (KR); Yoo Mi RA, Yongin-si (KR); Dong Yoon LEE, Yongin-si (KR); Seong Young LEE, Yongin-si (KR)

(21) Appl. No.: 18/632,178

(22) Filed: Apr. 10, 2024

(30) Foreign Application Priority Data
Jun. 19, 2023 (KR) 10-2023-0078012

(51) Int. Cl. H10K 59/131; H10K 59/80; H10K 102/00; H10K 102/10

(52) U.S. Cl. CPC H10K 59/131; H10K 59/87; H10K 2102/103; H10K 2102/3026

(57) ABSTRACT

A display device includes a substrate; a pixel electrode disposed in a display area of the substrate and a transistor connected to the pixel electrode; a gate driver disposed in a non-display area of the substrate and connected to a gate electrode of the transistor; and a common voltage line disposed in the non-display area of the substrate to overlap the gate driver in a plan view, where the common voltage line defines at least one exhaust hole penetrating the common voltage line therein.

This application claims priority to Korean Patent Application No. 10-2023-0078012, filed on Jun. 19, 2023, and all the benefits accruing therefrom under 35 U.S.C. § 119, the content of which in its entirety is herein incorporated by reference.

### BACKGROUND

### 1. Technical Field

The present disclosure relates to a display device, specifically a display device capable of minimizing a voltage drop of a common voltage.

### 2. Description of the Related Art

An organic light emitting display apparatus includes a display element in which luminance is changed by current, for example, an organic light emitting diode.

### SUMMARY

In an embodiment according to the present disclosure, a display device includes: a substrate; a pixel electrode disposed in a display area of the substrate and a transistor connected to the pixel electrode; a gate driver disposed in a non-display area of the substrate and connected to a gate electrode of the transistor; and a common voltage line disposed in the non-display area of the substrate to overlap the gate driver in a plan view, where the common voltage line defines at least one exhaust hole penetrating the common voltage line therein.

An organic light emitting display device includes a display element of which luminance is changed by current, for example, an organic light emitting diode.

In the display device according to the present disclosure, a common voltage line is connected to a common electrode on a gate driver of a non-display area. Accordingly, a contact area between the common voltage line and the common electrode may be increased. Therefore, a voltage drop (e.g., IR drop) of a common voltage applied from the common voltage line to the common electrode can be minimized.

In addition, according to the display device of the present invention, the common voltage line may have an exhaust hole penetrating therethrough, and thus the exhaust hole provides a path through which outgas of the organic film is discharged to prevent moisture from damaging the light emitting layer or the common electrode.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a plan view of a display device according to an embodiment;

FIG. 2 is a circuit diagram of a pixel of a display device according to an embodiment;

FIG. 3 is an enlarged view of part A of FIG. 1;

FIG. 4 is a cross-sectional view taken along line I-I′ of FIG. 3; and

FIG. 5 is a cross-sectional view of a pixel according to an embodiment.

### DETAILED DESCRIPTION

It will be understood that when an element is referred to as being “on” another element or “connected to” another element, it can be directly on or directly connected to the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Hereinafter, embodiments will be described in detail with reference to the accompanying drawings.

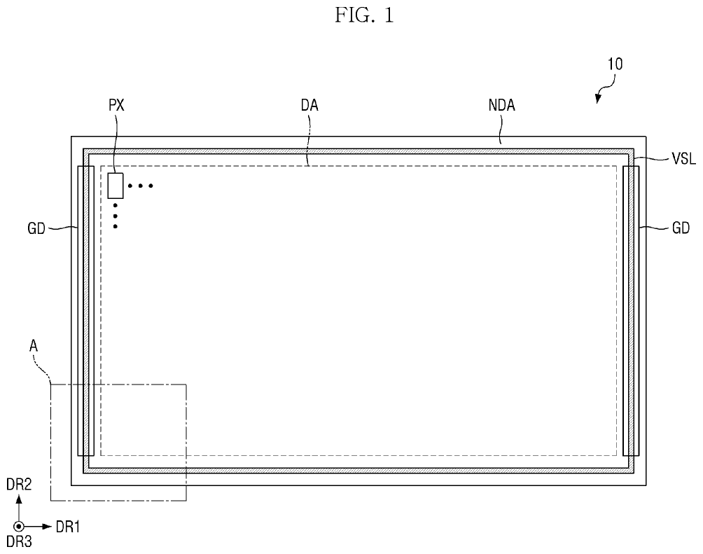

FIG. 1 is a plan view of a display device 10 according to an embodiment. As used herein, the “plan view” is a view in a thickness direction (i.e., third direction DR3) of the substrate.

Referring to FIG. 1, the display device 10 according to an embodiment may provide a screen. The display device 10 may have a shape similar to a rectangle having long sides in a first direction DR1 and short sides in a second direction DR2. A corner where the long side of the first direction DR1 and the short side of the second direction DR2 meet may be rounded to have a curvature. However, the present disclosure is not limited thereto, and the corner may be right-angled in another embodiment. The planar shape of the display device 1 is not limited to a rectangular shape, and may have other polygonal shapes, a circular shape, or elliptical shape in another embodiment.

The display device 10 may include a display area DA including pixels PX displaying an image and a non-display area NDA disposed around the display area DA. The display area DA may emit light from a plurality of emission areas or a plurality of opening areas. For example, the display device 10 may include a pixel circuit including switching elements, a pixel defining layer that defines the emission areas or the opening areas, and a self-light emitting element.

In an embodiment, for example, the self-light emitting element may include, but is not limited to, at least one of: an organic light emitting diode including an organic light emitting layer, a quantum dot light emitting diode (quantum LED) including a quantum dot light emitting layer, an inorganic light-emitting diode (inorganic LED) including an inorganic semiconductor, and a micro light emitting diode (micro LED).

The non-display area NDA may be disposed on the outer side of the display area DA. The non-display area NDA may be defined as the edge area of the display device 10. A gate driver GD that applies gate signals to gate lines, and fan-out lines (not shown) that connect a display driver 200 with the display area DA may be disposed in the non-display area NDA. Meanwhile, a plurality of gate drivers GD may be disposed in the non-display area NDA. In an embodiment, for example, as shown in FIG. 1, two gate drivers GD may be disposed on one side (e.g., left side) and the other side (e.g., right side) of the non-display area NDA, respectively, with the display area DA interposed therebetween.

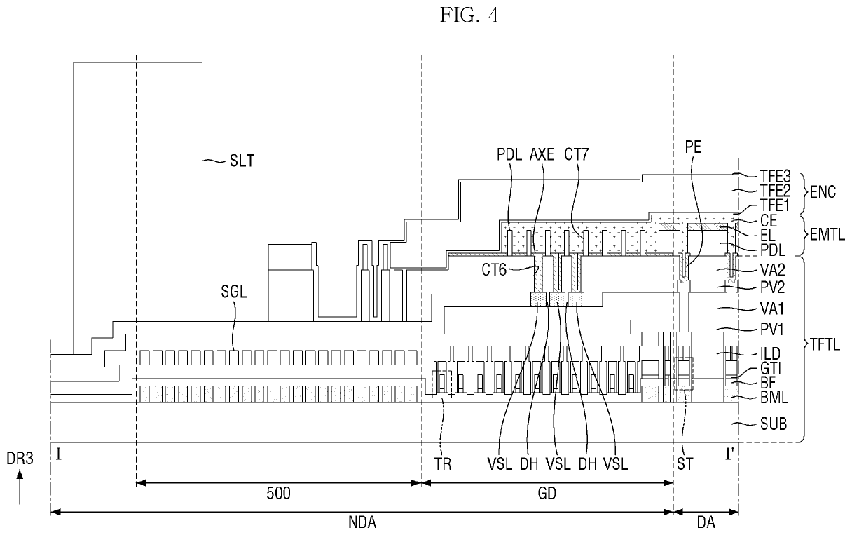

The gate driver GD may include a plurality of transistors (e.g., TR in FIG. 4). The gate driver GD may provide gate signals for driving the gate lines of the display area DA by using the plurality of transistors TR. Gate signals from the gate driver GD may be supplied to the pixels PX through gate lines.

In addition, a common voltage line VSL for transmitting a common voltage may be disposed in the non-display area NDA. The common voltage from the common voltage line VSL may be supplied to the pixels PX. As in the example shown in FIG. 1, the common voltage line VSL may have a closed curve shape surrounding the display area DA. Further, the common voltage line VSL may overlap the gate driver GD in a plan view.

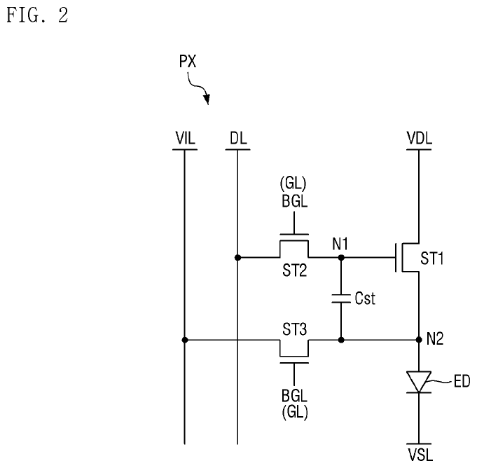

FIG. 2 is a circuit diagram of a pixel PX of a display device 10 according to an embodiment. In an embodiment, for example, the circuit diagram of the pixel PX of FIG. 2 may be a circuit diagram of the pixel PX of FIG. 1 described above.

Referring to FIG. 2, the pixel PX may be connected to a driving voltage line VDL, a data line DL, an initialization voltage line VIL, a gate line GL and a common voltage line VSL.

The pixel PX may include a first transistor ST1, a second transistor ST2, a third transistor ST3, a capacitor Cst and a light emitting element ED.

The first transistor ST1 may include a gate electrode, a drain electrode, and a source electrode. The gate electrode of the first transistor ST1 may be connected to a first node N1, the drain electrode of the first transistor ST1 may be connected to the driving voltage line VDL and the source electrode of the first transistor ST1 may be connected to a second node N2. The first transistor ST1 may control a drain-source current (or driving current) based on the data voltage applied to the gate electrode.

The light emitting element ED may emit light by receiving a driving current. The light emission amount or the luminance of the light emitting element ED may be proportional to the magnitude of the driving current. The light emitting element ED may be an organic light emitting diode (“OLED”) having an organic light emitting layer, a quantum dot light emitting diode (“LED”) including a quantum dot light emitting layer, a micro LED, or an inorganic LED having an inorganic semiconductor.

The first electrode of the light emitting element ED may be connected to the second node N2, and the second electrode of the light emitting element ED may be connected to the common voltage line VSL. The first electrode of the light emitting element ED may be connected to the source electrode of the first transistor ST1, the drain electrode of the third transistor ST3 and a second capacitor electrode of the capacitor Cst through the second node N2. The second electrode of the light emitting element ED may be connected to the common voltage line VSL.

The second transistor ST2 may be turned on by the gate signal of the gate line GL to electrically connect the data line DL to the first node N1 which is the gate electrode of the first transistor ST1. The second transistor ST2 may be turned on based on the gate signal to supply the data voltage to the first node N1. The gate electrode of the second transistor ST2 may be connected to the gate line GL, the drain electrode of the second transistor ST2 may be connected to the data line DL, and the source electrode of the second transistor ST2 may be connected to the first node N1. The source electrode of the second transistor ST2 may be connected to the gate electrode of the first transistor ST1 and a first capacitor electrode of a capacitor Cst through the first node N1. The gate electrode of the second transistor ST2 may be connected to the gate driver GD through the gate line GL. The gate driver GD may supply the gate signal to the gate electrode of the second transistor ST2 through the gate line GL.

The third transistor ST3 may be turned on by the gate signal of the gate line GL to electrically connect the initialization voltage line VIL to the second node N2 which is the source electrode of the first transistor ST1. The third transistor ST3 may be turned on based on the gate signal to supply the initialization voltage to the second node N2. The third transistor ST3 may be turned on based on the gate signal to supply the sensing signal to the initialization voltage line VIL. The gate electrode of the third transistor ST3 may be connected to the gate line GL, the drain electrode of the third transistor ST3 may be connected to the second node N2, and the source electrode of the third transistor ST3 may be connected to the initialization voltage line VIL. The drain electrode of the third transistor may be connected to the source electrode of the first transistor ST1, a second capacitor electrode of the capacitor Cst and a first electrode of the light emitting element ED through the second node N2. The gate electrode of the third transistor ST3 may be connected to the gate driver GD through the gate line GL. The gate driver GD may supply a gate signal to the gate electrode of the third transistor ST3 through the gate line GL.

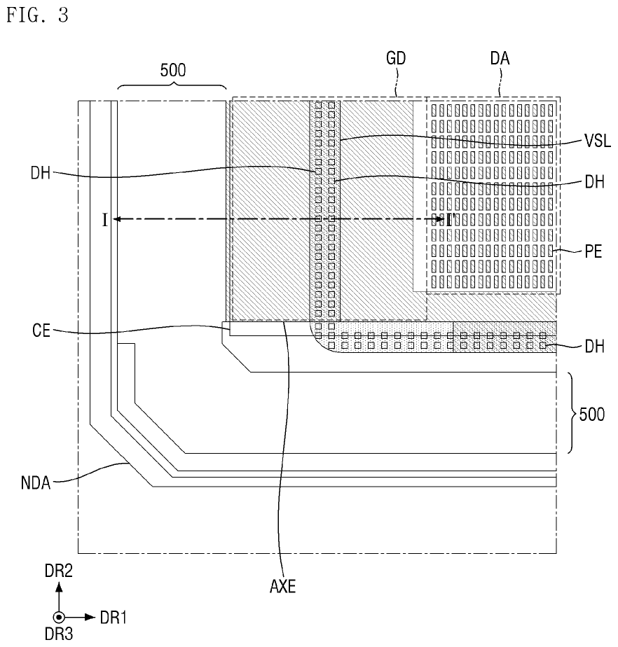

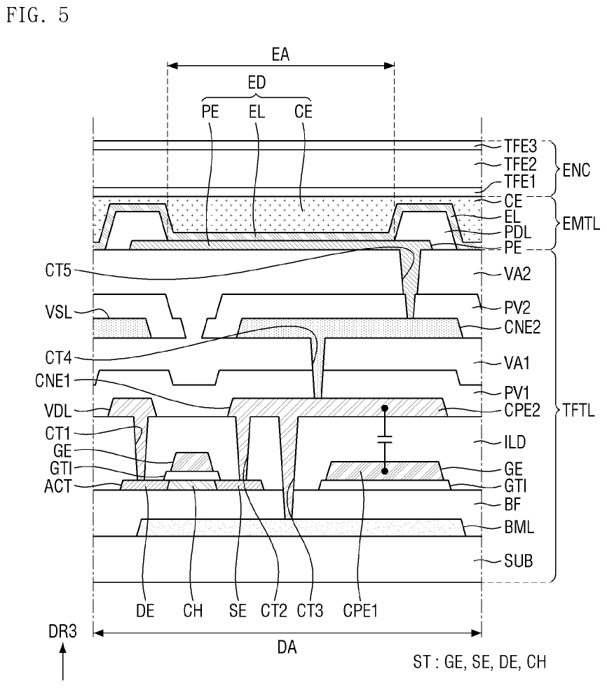

FIG. 3 is an enlarged view of part A of FIG. 1, FIG. 4 is a cross-sectional view taken along line I-I′ of FIG. 3, and FIG. 5 is a cross-sectional view of a pixel according to an embodiment.

As shown in FIG. 3, a gate control signal transmission line 500 for transmitting a gate control signal and the like to the gate driver GD may be disposed on one side of the gate driver GD. The gate driver GD may generate gate signals based on the gate control signal.

As shown in FIG. 4, the gate control signal transmission line 500 may include a plurality of signal lines SGL.

As shown in FIG. 4, the gate driver GD may include a plurality of transistors TR for generating gate signals based on the gate control signal.

In FIG. 4, the transistor ST in the display area DA may be, for example, any one of the first to third transistors ST1, ST2, and ST3 described above.

As shown in FIGS. 4 and 5, the display device 10 may include a substrate SUB, a thin film transistor layer TFTL, a light emitting element layer EMTL, and an encapsulation layer ENC. The thin film transistor layer TFTL, the light emitting element layer EMTL, and the encapsulation layer ENC may be sequentially disposed on the substrate SUB along a third direction DR3.

The substrate SUB may be a rigid substrate or a flexible substrate which can be bent, folded or rolled. The substrate SUB may be formed of an insulating material such as glass, quartz, or a polymer resin. Examples of a polymer material may include polyethersulphone (“PES”), polyacrylate (“PA”), polyarylate (“PAR”), polyetherimide (“PEI”), polyethylene naphthalate (“PEN”), polyethylene terephthalate (“PET”), polyphenylene sulfide (“PPS”), polyallylate, polyimide (“PI”), polycarbonate (“PC”), cellulose triacetate (“TAC”), cellulose acetate propionate (“CAP”), or a combination thereof. Alternatively, the substrate SUB may include a metal material.

As shown in FIGS. 4 and 5, a light blocking layer BML may be disposed on the substrate SUB. In an embodiment, for example, the light blocking layer BML may be disposed on the substrate SUB to overlap the gate electrode of the first transistor ST1 and a channel region CH of the first transistor ST1 in a plan view. The light blocking layer BML may be made of, for example, a metallic material such as chromium (Cr) or molybdenum (Mo), black ink, black dye, or the like. When the light blocking layer BML is made of a metallic material, the light blocking layer BML may be supplied with a constant power source. In an embodiment, for example, the light blocking layer BML may be connected to the source electrode SE of the first transistor ST1 through a first connection electrode CNE1 to be described later. In this way, the light blocking layer BML is not electrically floating, and the transistors on the light blocking layer BML may have its electrical characteristics stabilized. In addition, the light blocking layer BML may prevent light from outside from being incident into the channel region CH of an active layer ACT. In this way, for example, performance degradation of the oxide-based first transistor ST1 may be minimized. On the other hand, since the oxide semiconductor is sensitive to light, fluctuations in the amount of current or the like may occur due to external light.

As shown in FIGS. 4 and 5, a buffer layer BF may be disposed on the light blocking layer BML. The buffer layer BF may be disposed on the entire surface of the substrate SUB including the light blocking layer BML. The buffer layer BF may be a layer for protecting the transistors ST1 to ST3 of the thin film transistor layer TFTL and a light emitting layer EL of the light emitting element layer EMTL from moisture permeating through the substrate SUB that is susceptible to moisture permeation. The buffer layer BF may be formed as a plurality of inorganic layers that are alternately stacked. In an embodiment, for example, the buffer layer BF may be formed of multiple layers in which one or more inorganic layers of a silicon nitride layer, a silicon oxynitride layer, a silicon oxide layer, a titanium oxide layer and an aluminum oxide layer are alternately stacked.

As shown in FIGS. 4 and 5, the active layer ACT may be disposed on the buffer layer BF. The active layer ACT may be disposed to overlap the light blocking layer BML in a plan view. As shown in FIG. 5, the active layer ACT may include a source electrode SE, a drain electrode DE, and a channel region CH of the first transistor ST1. The active layer ACT may be an active layer made of low temperature polycrystalline silicon (“LTPS”). As another embodiment, the active layer ACT may be an oxide-based active layer. In an embodiment, for example, the active layer ACT may be an oxide semiconductor containing indium-gallium-zinc oxide (“IGZO”) or indium-gallium-zinc-tin oxide (“IGZTO”).

As shown in FIGS. 4 and 5, a gate insulating layer GTI may be disposed on the active layer ACT and the buffer layer BF. In an embodiment, for example, as shown in FIG. 5, the gate insulating layer GTI may be disposed between a gate electrode GE and the active layer ACT. In addition, the gate insulating layer GTI may be disposed between the buffer layer BF and the gate electrode GE. In FIG. 5, the gate electrode GE overlapping the active layer ACT and the gate electrode not overlapping the active layer ACT in a plan view may be integrally formed. On the other hand, the gate insulating layer GTI may not be disposed on the source electrode SE and the drain electrode DE. The gate insulating layer GTI may include at least one of tetraethyl orthosilicate (“TEOS”), silicon nitride (SiNx), or silicon oxide (SiO₂). In an embodiment, for example, the gate insulating layer GTI may have a double layer structure in which a silicon nitride layer having a thickness of 40 nanometers (nm) and a tetraethyl orthosilicate layer having a thickness of 80 nm are sequentially stacked.

The gate electrode GE may be disposed on the gate insulating layer GTI. The gate electrode GE may be disposed on the gate insulating layer GTI to overlap the channel region CH of the active layer ACT in a plan view. The gate electrode GE may include a first capacitor electrode CPE1. In an embodiment, for example, the gate electrode GE may be extended to overlap the light blocking layer BML in a plan view (or a first connection electrode CNE1 which will be described later), and thus the extended portion of the gate electrode GE may correspond to the first capacitor electrode CPE1 of the capacitor Cst. The gate electrode GE may be a single layer or a multilayer including one or more of molybdenum (Mo), copper (Cu), and titanium (Ti).

As shown in FIGS. 4 and 5, an interlayer-insulating layer ILD may be disposed on the gate electrode GE. The interlayer-insulating layer ILD may be disposed on the entire surface of the substrate SUB including the gate electrode GE. The interlayer-insulating layer ILD may include an inorganic layer, for example, a silicon nitride layer, a silicon oxynitride layer, a silicon oxide layer, a titanium oxide layer, or an aluminum oxide layer. In another embodiment, the interlayer-insulating layer ILD may include a plurality of inorganic layers.

As shown in FIGS. 4 and 5, a driving voltage line VDL and a first connection electrode CNE1 may be disposed on the interlayer-insulating layer ILD. As shown in FIG. 5, the driving voltage line VDL may be connected to the drain electrode DE of the active layer ACT through a first contact hole CT1 penetrating the interlayer-insulating layer ILD, and the first connection electrode CNE1 may be connected to the source electrode SE of the active layer ACT through a second contact hole CT2 penetrating the interlayer-insulating layer ILD. In addition, the first connection electrode CNE1 may be connected to the light blocking layer BML through a third contact hole CT3 penetrating the interlayer-insulating layer ILD and the buffer layer BF.

In addition, the first connection electrode CNE1 may be disposed to overlap the first capacitor electrode CPE1 in a plan view, and thus the extended portion of the first connection electrode CNE1 may correspond to the second capacitor electrode CPE2 of the capacitor CST. The capacitor Cst described above may be formed in a region overlapping the first capacitor electrode CPE1 and the second capacitor electrode CPE2 in a plan view.

A first passivation layer PV1 may be disposed on the driving voltage line VDL and the first connection electrode CNE1. The first passivation layer PV1 may be formed of an inorganic layer, and function as an insulating layer.

On the first passivation layer PV1, for example, a pad electrode (not shown) may be disposed.

A first planarization layer VA1 may be disposed on the pad electrode. In an embodiment, the first planarization layer VA1 may include an organic layer such as acryl resin, epoxy resin, phenolic resin, polyimide resin, polyimide resin and the like, and function as an insulating layer.

As shown in FIGS. 4 and 5, a common voltage line VSL and a second connection electrode CNE2 may be disposed on the first planarization layer VA1. The second connection electrode CNE2 may be connected to the first connection electrode CNE1 through a fourth contact hole CT4 penetrating the first planarization layer VA1 and the first passivation layer PV1. The common voltage line VSL, for example, may have a triple layer structure formed of a first layer including Ti, a second layer including Cu and a third layer including ITO. Here, the first to third layers may be stacked along the third direction DR3. Similarly, the second connection electrode CNE2 may have a triple layer structure formed of a first layer including Ti, a second layer including Cu and a third layer including ITO.

As shown in FIGS. 4 and 5, a second passivation layer PV2 may be disposed on the common voltage line VSL and the second connection electrode CNE2. The second passivation layer PV2 may be formed of the same material as the first passivation layer PV1, and function as an insulating layer.

A second planarization layer VA2 may be disposed on the second passivation layer PV2. The second planarization layer VA2 may be formed of the same material as the first planarization layer VA1, and function as an insulating layer.

The light emitting element layer EMTL including the pixel electrode PE may be disposed on the second planarization layer VA2. In an embodiment, for example, as shown in FIG. 5, the pixel electrode PE may be connected to the second connection electrode CNE2 through a fifth contact hole CT5 penetrating the second planarization layer VA2 and the second passivation layer PV2.

Other than the pixel electrode PE described above, the light emitting element layer EMTL described above may further include banks PDL (or pixel defining layer) defining an emission area EA.

The light emitting element ED may include a pixel electrode PE, a light emitting layer EL and a common electrode CE.

In a top emission structure that emits light toward the common electrode CE with respect to the light emitting layer EL, the pixel electrode PE1 may be formed of a single layer of molybdenum (Mo), titanium (Ti), copper (Cu), or aluminum (Al), or may be formed to have a laminated structure of aluminum and titanium (Ti/Al/Ti), a laminated structure of aluminum and ITO (ITO/Al/ITO), an APC alloy, or a laminated structure of APC alloy and ITO (ITO/APC/ITO) to increase the reflectivity. The APC alloy is an alloy of silver (Ag), palladium (Pd) and copper (Cu).

The bank PDL (or pixel defining layer) may serve to define the emission area EA of the pixel PX. To this end, the bank PDL may be formed to expose each partial region of the pixel electrode PE on the second planarization layer VA2. The bank PDL may cover the edge of the pixel electrode PE. In an embodiment, the bank PDL may be formed of an organic layer such as acryl resin, epoxy resin, phenolic resin, polyamide resin, polyimide resin and the like, and function as an insulating layer.

The light emitting layer EL may be disposed on the pixel electrode PE. The light emitting layer EL may include an organic material to emit light in a predetermined color. In an embodiment, for example, the light emitting layer EL may include a hole transporting layer, an organic material layer, and an electron transporting layer. The organic material layer may include a host and a dopant. The organic material layer may include a material that emits predetermined light, and may be formed using a phosphorescent material or a fluorescent material.

In an embodiment, for example, the light emitting layer EL may be a light emitting layer that emits blue light, and in this case, such organic material layer of the blue light emitting layer may include a host material including CBP or mCP and may be a fluorescent material including dopant material including (4,6-F2ppy)2Irpic or L2BD111.

When the light emitting layer EL is a blue light emitting layer, a red quantum dot layer, a green quantum dot layer and a transparent layer (e.g., overcoat layer) may be disposed for each pixel on the upper portion of the light emitting layer. In an embodiment, for example, the red quantum dot layer may be disposed on the light emitting layer of the red pixel, the green quantum dot layer may be disposed on the light emitting layer of the green pixel, and the transparent layer may be disposed on the light emitting layer of the blue pixel.

The common electrode CE may be disposed on the light emitting layer EL. The common electrode CE may be disposed to cover the light emitting layer EL. In another embodiment, although not shown in the drawing, a capping layer may be disposed on the common electrode CE.

In the top emission structure, the common electrode CE may be formed of a transparent conductive material (“TCO”) such as ITO or IZO capable of transmitting light or a semi-transmissive conductive material such as magnesium (Mg), silver (Ag), or an alloy of magnesium (Mg) and silver (Ag). When the common electrode CE is formed of a semi-transmissive conductive material, the light emission efficiency can be increased due to a micro-cavity effect.

An encapsulation layer ENC may be disposed on the light emitting element layer EMTL. The encapsulation layer ENC may include at least one inorganic layer TFE1 or TFE3 to prevent oxygen or moisture from permeating into the light emitting element layer EMTL. In addition, the encapsulation layer ENC may include at least one organic layer to protect the light emitting element layer EMTL from foreign substances such as dust. In an embodiment, for example, the encapsulation layer ENC may include a first inorganic encapsulation layer TFE1, an organic encapsulation layer TFE2, and a second inorganic encapsulation layer TFE3.

The first inorganic encapsulation layer TFE1 may be disposed on the common electrode CE, the organic encapsulation layer TFE2 may be disposed on the first inorganic encapsulation layer TFE1, and the second inorganic encapsulation layer TFE3 may be disposed on the organic encapsulation layer TFE2. The first inorganic encapsulation layer TFE1 and the second inorganic encapsulation layer TFE3 may be formed of multiple layers in which one or more inorganic layers of a silicon nitride layer, a silicon oxynitride layer, a silicon oxide layer, a titanium oxide layer and an aluminum oxide layer are alternately stacked. The organic encapsulation layer TFE2 may be an organic layer such as acryl resin, epoxy resin, phenolic resin, polyimide resin, polyimide resin or the like.

As shown in FIG. 4, an auxiliary electrode AXE may be further disposed on the second planarization layer VA2. The auxiliary electrode AXE may be formed of the same material as the pixel electrode PE described above. In addition, the auxiliary electrode AXE may be disposed on the same layer as the pixel electrode PE. The auxiliary electrode AXE may be connected to the common voltage line VSL through a sixth contact hole CT6 penetrating the second planarization layer VA2 and the second passivation layer PV2. In an embodiment, for example, in the non-display area NDA, the auxiliary electrode AXE may be connected to the common voltage line VSL of the non-display area NDA through the sixth contact hole CT6. In other words, the auxiliary electrode AXE and the common voltage line VSL may be connected in the non-display area NDA. In this case, the contact portion (e.g., the sixth contact hole CT6) between the auxiliary electrode AXE and the common voltage line VSL, for example, may overlap the gate driver GD disposed in the non-display area NDA in a plan view.

The auxiliary electrode AXE may have a closed curve shape surrounding the display area DA. The auxiliary electrode AXE may overlap the common voltage line VSL in a plan view. In an embodiment, for example, the auxiliary electrode AXE may have the same shape as the common voltage line VSL shown in FIG. 1. In this case, the auxiliary electrode AXE may overlap the entire portion of the common voltage line VSL in a plan view. In one embodiment, the auxiliary electrode AXE may overlap the common voltage line VSL while having an area greater than the common voltage line VSL in a plan view.

In addition, the common electrode CE may be connected to the auxiliary electrode AXE through a seventh contact hole CT7 penetrating the bank PDL. In an embodiment, for example, the common electrode CE may be connected to the auxiliary electrode AXE of the non-display area NDA through the seventh contact hole CT7 in the non-display area NDA. In other words, the common electrode CE and the auxiliary electrode AXE may be connected in the non-display area NDA. In this case, the contact portion (e.g., seventh contact hole CT7) between the common electrode CE and the auxiliary electrode AXE, for example, may overlap the gate driver GD disposed in the non-display area NDA in a plan view. Accordingly, the common electrode CE may be connected to the common voltage line VSL through the auxiliary electrode AXE. In this case, the common electrode CE may be connected to the common voltage line VSL on the gate driver GD in the non-display area NDA. In other words, the contact portions (e.g., the sixth contact hole CT6 and the seventh contact hole CT7) between the common electrode CE and the common voltage line VSL may overlap the gate driver GD in the third direction DR3. The sixth contact hole CT6 and the seventh contact hole CT7 may be disposed in the non-display area NDA.

As described above, the common voltage line VSL may surround the non-display area NDA and be connected to the common electrode CE on the gate driver GD (or the plurality of gate drivers GD) of the non-display area NDA, and thus, accordingly, the contact area between the common voltage line VSL and the common electrode CE may increase. In other words, since the common voltage line VSL is connected to the common electrode CE even on the gate driver GD of the non-display area NDA, the total contact area between the common voltage line VSL and the common electrode CE may be effectively improved (i.e., increased). Accordingly, a voltage drop (e.g., IR drop) of the common voltage applied from the common voltage line VSL to the common electrode CE may be minimized.

As another embodiment, the common electrode CE may overlap the entire portion of the common voltage line VSL in the non-display area NDA in a plan view, and the common electrode CE may be in contact with the common voltage line VSL through the auxiliary electrode AXE in the overlapping area. In this case, the contact area between the common electrode CE and the common voltage line VSL may further increase and further minimize the voltage drop of the common voltage.

As shown in FIGS. 3 and 4, the common voltage line VSL may define at least one exhaust hole DH therein. The exhaust hole DH may penetrate the common voltage line VSL. The exhaust hole DH of the common voltage line VSL, for example, may discharge outgas of an organic layer (e.g., first planarization layer VA1). Since the first planarization layer VA1 is formed of resin such as photo acryl and polyimide, moisture can be absorbed when exposed to the air. As a result, moisture may remain in the first planarization layer VA1, and the light emitting layer EL or the common electrode CE may be damaged by the outgas of the first planarization layer VA1. The exhaust hole DH of the common voltage line VSL may provide a path through which the outgas of the first planarization layer VA1 is discharged, thereby preventing moisture from damaging the light emitting layer EL or the common electrode CE.

At least one exhaust hole DH of the common voltage line VSL may overlap the first planarization layer VA1 in the third direction DR3.

As shown in FIG. 4, a sealant SLT may be disposed on the first passivation layer PV1 in the non-display area NDA. The sealant SLT may be disposed between the substrate SUB and the encapsulation substrate (not shown) to seal the substrate SUB and the encapsulation substrate.

What is claimed is:

1. A display device comprising:
a substrate;
a pixel electrode disposed in a display area of the substrate and a transistor connected to the pixel electrode;
a gate driver disposed in a non-display area of the substrate and connected to a gate electrode of the transistor; and
a common voltage line disposed in the non-display area of the substrate to overlap the gate driver in a plan view,
wherein the common voltage line defines at least one exhaust hole penetrating the common voltage line therein.

2. The display device of claim 1,
wherein the common voltage line surrounds the display area in the plan view.

3. The display device of claim 1, further comprising an auxiliary electrode connected to the common voltage line through a contact hole of a first insulating layer.

4. The display device of claim 3,
wherein the contact hole of the first insulating layer is disposed in the non-display area.

5. The display device of claim 3, further comprising a common electrode connected to the auxiliary electrode through a contact hole of a second insulating layer.

6. The display device of claim 5,
wherein the contact hole of the second insulating layer is disposed in the non-display area.

7. The display device of claim 5,
wherein the auxiliary electrode is formed of a same material as the pixel electrode.

8. The display device of claim 5,
wherein the auxiliary electrode is disposed in a same layer as the pixel electrode.

9. The display device of claim 1,
wherein the gate driver is provided in plural.

10. The display device of claim 9,
the plurality of gate drivers are disposed on each of one side and an opposite side of the non-display area facing each other with the display area disposed therebetween.

11. The display device of claim 1, further comprising a passivation layer and a planarization layer sequentially stacked and disposed between the gate driver and the common voltage line.

12. The display device of claim 11,
wherein the at least one exhaust hole of the common voltage line overlaps the planarization layer in the plan view.

13. The display device of claim 11,
wherein the planarization layer is an organic layer.

14. The display device of claim 11,
wherein the passivation layer is an inorganic layer.
